(19) United States
(12) Patent Application Publication
(10) Pub. No.: US 2012/0294461 A1
(43) Pub. Date: Nov. 22, 2012

(54) SOUND EQUIPMENT, VOLUME CORRECTING APPARATUS, AND VOLUME CORRECTING METHOD

(75) Inventors: Masanobu MAEDA, Kobe-shi (JP); Nobutaka MIYAUCHI, Kobe-shi (JP); Fumitake NAKAMURA, Kobe-shi (JP); Masahiko KUBO, Kobe-shi (JP); Nahoko KAWAMURA, Kobe-shi (JP); Machiko MATSUI, Kobe-shi (JP); Hideto SAITOH, Kobe-shi (JP); Hiroyuki KUBOTA, Kobe-shi (JP); Masayuki TAKAOKA, Kobe-shi (JP); Masanobu WASHIO, Kobe-shi (JP); Yutaka NISHIOKA, Kobe-shi (JP); Osamu YASUTAKE, Kobe-shi (JP)

(73) Assignee: FUJITSU TEN LIMITED, Kobe-shi (JP)

(21) Appl. No.: 13/469,775

(22) Filed: May 11, 2012

(30) Foreign Application Priority Data
May 16, 2011 (JP) 2011-109741

(51) Int. Cl. H03G 3/20

(52) U.S. Cl. 381/107

(57) ABSTRACT

Sound equipment is configured to average an average value of a signal level at each predetermined frequency band of a sound signal at a different averaging time, to weight the average value calculated at a different averaging time by using an individual weighting value, to obtain a representative value based on a weighted average value, to determine a gain of a sound signal based on an obtained representative value, to correct a volume based on the corresponding gain, and to correct a volume based on the gain. The representative value is obtained by selecting the average value at which a gain becomes minimum within each weighted average value. The averaging performs at least a first averaging using the averaging time corresponding to the sound signal that the signal level changes rapidly, and a second averaging using the averaging time longer than the averaging time of the first averaging.

### CROSS-REFERENCE TO RELATED APPLICATION

This application is based upon and claims the benefit of priority of the prior Japanese Patent Application No. 2011-109741, filed on May 16, 2011, the entire contents of which are incorporated herein by reference.

### BACKGROUND OF THE INVENTION

1. Field of the Invention

Embodiments relate to sound equipment, a volume correcting apparatus, and a volume correcting method.

2. Description of the Related Art

Conventionally, there have been known sound equipment, such as radio tuners, CD (compact disc) players, or the like, which reproduces sound signals of a plurality of sound sources. Also, such sound equipment is also abundant in types, like stationary component audios, automotive sound equipment, or the like.

Particularly, in automotive sound equipment, diversification of sound sources reproduced has been progressing due to the fusion of car navigation system or the cooperation of portable digital music players in recent years, just like DVD (digital versatile disc), DTV (digital television) tuner, AUX (auxiliary) port input, or the like.

Meanwhile, it is usual that characteristics of each sound source are different from one another, as shown in a reproduction band or a signal type such as analog and digital. The difference of such characteristics is easy to cause a change in a reproduction volume at the time of switching the sound source, which also tend to give an uncomfortable feeling to listeners.

Also, by the spread of portable digital music players that are connected to AUX ports, the occurrence of such a change in a reproduction volume between pieces of music of the same sound source (that is, between sound contents) as well as at the time of switching the sound source is easily noticeable.

Accordingly, disclosed is a technology that calculates a gain based on a signal level value of a sound signal at the time of switching a sound source or music, and corrects a volume based on such a gain, so as not to cause such a change in a volume (for example, see Japanese Patent Application Laid-Open No. 2001-359184). Herein, in regard to the signal level value, an average value of the signal level over a given period of time, or the like, is often used.

However, in the case of using the conventional technology, since a volume correction is insufficient, there is a problem that may not wipe an uncomfortable feeling given to a listener. For example, music includes a plurality of reproduction bands in a piece of music, and the change over a given period of time also widely varies from rapidly to gradually. Therefore, when calculating the average value of the signal level of such music, it was very difficult just to determine an appropriate averaging time.

Also, in regard to the above-described gain, when calculating an appropriate gain, it is suitable to analyze the transition of signal levels of the entire music in advance prior to the reproduction of music. However, in the case of using such a method, it is highly likely that a large processing load is easy to impose to sound equipment, and a volume correction may not be performed quickly. That is, it is likely to give an uncomfortable feeling to listeners.

For these reasons, a big problem is how to realize sound equipment and a volume correcting method capable of correcting a volume such that no uncomfortable feeling is given to listeners. Also, such a problem is a problem that arises equally for a volume correcting apparatus specialized in a volume correction.

### SUMMARY OF THE INVENTION

A sound equipment for reproducing a sound signal according to one aspect of an embodiment includes a plurality of averaging units, a weighting unit, a representative value determining unit, and a volume correcting unit. The plurality of averaging units configured to average an average value of a signal level at each predetermined frequency band of the sound signal at a different averaging time. The weighting unit configured to weight the average value obtained by the averaging units by using an individual weighting value. The representative value determining unit configured to obtain a representative value based on the weighted average value. The volume correcting unit configured to determine a gain of the sound signal based on the representative value, and correct a volume based on the corresponding gain.

Also, a volume correcting apparatus for correcting a volume of a sound signal based on a volume correction amount set according to a variation in a signal level of the sound signal according to one aspect of an embodiment includes an initial volume correction amount setting unit, a signal level detecting unit, a correction amount deriving unit, and a volume correction amount updating unit. The initial volume correction amount setting unit configured to set the volume correction amount according to a signal level of an initial part of voice information. The signal level detecting unit configured to sequentially detect the signal level of the voice information in order of reproduction. The correction amount deriving unit configured to derive a volume correction amount update value according to the signal level detected by the signal level detecting unit. The volume correction amount updating unit configured to update the volume correction amount with the volume correction update value, when a volume is further reduced in a control by the volume correction amount update value than a control by the set volume correction amount.

Also, the invention provides sound equipment having a function of adjusting a reproduction volume depending on sound content and including a signal level detecting unit configured to sequentially detect a signal level of the sound content, and a level adjusting unit configured to adjust a sound signal level of the sound content to an adjusted value corresponding to a maximum value of the signal level detected by the signal level detecting unit.

The above, other objects, features and advantages of the invention will become apparent from the following description in conjunction with the drawings.

### BRIEF DESCRIPTION OF THE DRAWINGS

FIG. 1 is a time chart representing a music waveform, a target level, and a variation in a gain of an amplifier;

FIG. 2 is a configuration diagram illustrating main components of a volume correction;

FIG. 3 is a block diagram illustrating a configuration of a volume correction processing unit;

FIG. 4 is a diagram illustrating an example of a table corresponding to a signal level and a correction value;

FIG. 5 is a flow chart illustrating a volume correction processing that is performed by a DSP;

FIG. 6 is a diagram illustrating a transition of an input sound signal;

FIG. 7A is a diagram illustrating an outline of calculating a signal level value of a sound signal;

FIG. 7B is a diagram illustrating a difference in characteristics due to a difference in averaging time;

FIG. 7C is a diagram illustrating a brief overview of an example of the volume correcting method;

FIG. 8 is a diagram illustrating a configuration example of sound equipment;

FIG. 9 is a diagram illustrating a configuration example of a processing block of a DSP;

FIG. 10A is a diagram illustrating a pass band of a first BPF;

FIG. 10B is a diagram illustrating a pass band of a second BPF;

FIG. 11 is a diagram illustrating a configuration example of a first integration circuit and a second integration circuit;

FIGS. 12A and 12B are explanatory diagrams of weighting factor information;

FIGS. 13A and 13B are diagrams illustrating a modified example of a weighting factor setting;

FIGS. 14A and 14B are diagrams illustrating a configuration example of a selecting unit; and

FIG. 15 is a flow chart illustrating a processing procedure of a processing performed by a DSP.

### DETAILED DESCRIPTION OF THE PREFERRED EMBODIMENT

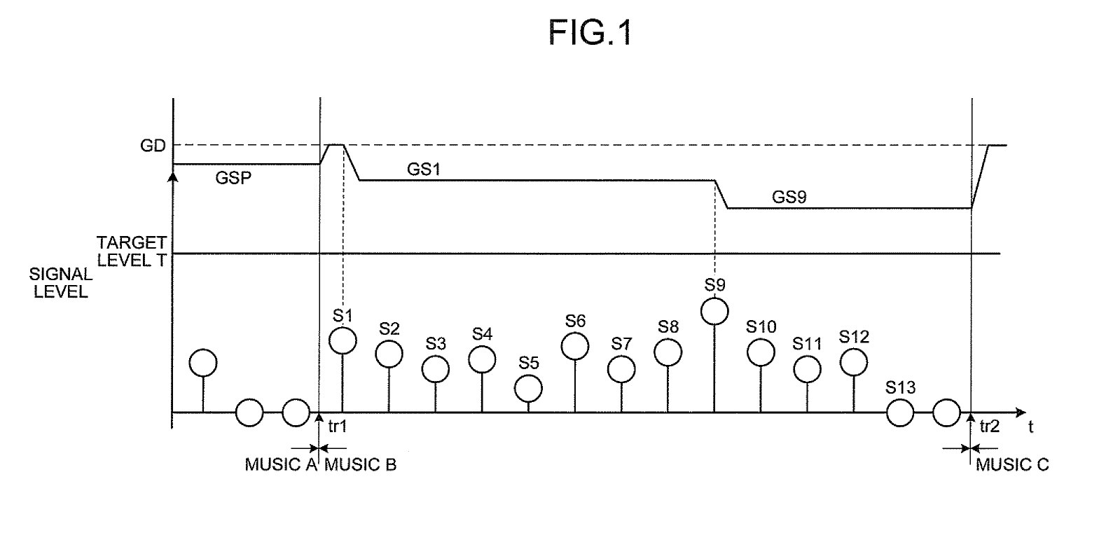

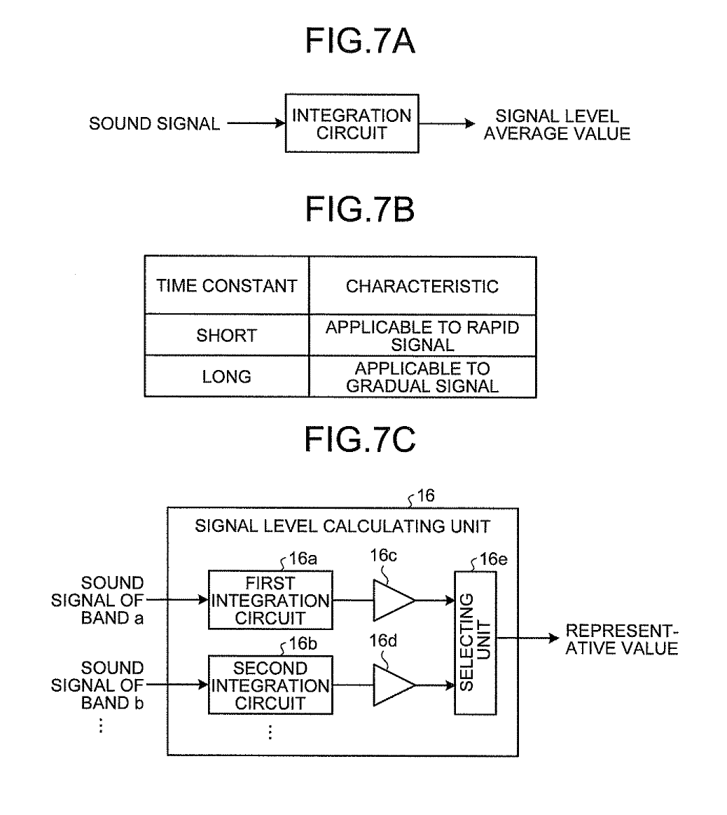

Hereinafter, an exemplary embodiment of a volume correcting method will be described in detail with reference to the accompanying drawings. Also, first, regarding parts realizing a basic function of an example of a volume correcting method according to an embodiment, the configuration, operation, and the like thereof will be described with reference to FIGS. 1 to 6. Then, regarding more detailed function, the configuration, operation, and the like will be described with reference to FIG. 7A or later. Also, hereinafter, the case where sound data being a volume correction target is mainly music will be described. Also, there are cases where sound data or sound signals corresponding to such music unit are described as “sound content” or “voice information”.

[Regarding Basic Function]

A volume correction of a sound signal determines a gain of an amplifier (attenuance of an attenuator) based on, ideally, a level distribution (basically a maximum level) of entire music ideally. However, in the case of this method, there is a problem that a reproduction is not performed quickly because it is necessary to determine a gain by performing an analysis across the entire music before reproducing the music, a processing load is large, and it takes a time to determine the gain.

Therefore, a basic volume correction operation of the embodiment corrects a volume while reproducing the music and monitoring a signal level value. For example, the basic volume correction operation is based on an operation that performs a volume correction based on a moving average value of a signal level value. Also, in this case, a method of determining a correction value by monitoring a head part during a predetermined period of time and then using the correction value (during the reproduction of the corresponding music), a method of further adding a processing of primarily lowering a volume if a signal exceeding a maximum value is detected thereafter, or the like is applied.

Also, there is a technology that corrects a difference in signal levels between sound sources or between pieces of music of the same sound source, and maintains the reproduction at a user's favorite volume even though the sound sources or the pieces of music are changed. This technology is roughly divided into “application of sound compressor technology” and “method using a psychoacoustic model”.

The “application of sound compressor technology” is a processing based on a technology of compressing a dynamic range depending on a signal level. This technology is done with a relatively small amount of processing, but a dynamic range of music is reduced. Therefore, there is a problem as it is said that the inherent sound quality or intonation expression is sacrificed. On the other hand, the “method using a psychoacoustic model” is a technology of analyzing characteristics of a sound signal from a human auditory filter model at each frequency band, leading to an optimal volume balance of audibility, and correcting a difference. A natural audibility may be obtained, but an amount of analysis processing such as an audibility filter or the like is increased, causing cost increase due to the necessity of a dedicated correction integrated circuit, or the like.

With regard to such problems, a volume correcting method of the embodiment realizes a volume correction in a relatively small amount of processing amount (or in a relatively small circuit size) while suppressing degradation of sound quality or the like.

From these objects, basic characteristics on the operation of this volume correcting method are as follows. Also, actual control carries out a processing such that control is performed according to the characteristic, considering suppression of a processing load or a reproduction time delay.

First, if a level of a sound signal is always corrected while one piece of music is reproduced, there is a risk of a variation in volume or degradation in expression of music intonation, and a change in tone due to a change in a correction value. Hence, during the same music (interval caught as the same music), a correction value is basically maintained. Second, a correction value is a difference between an average level and a target level of the corresponding music. Third, when a user actually manipulates a volume, a correction value is lowered only when an input signal is large, rather than frequent correction, on the assumption that the user does not finely manipulate within one piece of music.

Next, control contents of the volume correcting method will be described by showing an example of a music waveform. Also, a main hard configuration of a volume correction is disposed at a preceding stage of a user's manipulating volume and, in an amplifier circuit functioning as an internal volume, performs a volume correction to control a gain (amplification factor or attenuation factor) of the corresponding amplifier circuit. FIG. 1 is a time chart representing a music waveform (indicated by an AD conversion value of a predetermined sampling timing), a target level, and a variation in a gain of an amplifier.

While music A is being reproduced, a gain of an amplifier becomes a gain GSP corresponding to a signal level of the music A. Then, at a timing tr1 at which music changes (for example, a change of music information (track number) on a music disc or the like and a change of music such as a duration of a silent part or the like are detected and a trigger signal is outputted), a gain is changed to an initial gain GD.

After that, a gain is calculated based on a signal level of an initial part (so-called head part) of newly played music B (signal level at an initial sampling timing) and an average signal level of a predetermined number of sampling timing (when a predetermined period of time has elapsed: that is, being an average level of the initial part of the music), or the like, and the amplifier is controlled. In this example, a gain GS1 is calculated based on a signal level S1 at an initial sampling timing, and the amplifier is controlled.

Also, the signal level is calculated by performing a so-called moving average processing on a sound signal that has been filtered using an integration filter (low pass filter) having an appropriate time constant. Also, in this example, a reset processing accompanying the music change (trigger tr) of the moving average processing is not performed.

Since subsequent signal levels S2 to 58 are lower than the signal level S1, the gain GS1 is maintained. Then, since a signal level S9 exceeds the signal level S1, a new gain GS9 is calculated, and the amplifier is controlled by the gain GS9. Then, since the signal level does not exceed the signal level 59 until the music B is ended, the gain GS9 is maintained until the end of the music. Then, the reproduction is moved to next music C, the similar processing to the music B (again, the processing is performed from the resetting of the gain) is started based on a music change trigger signal tr2. Also, even at the time of the initial music reproduction, such as at the time of power on, or the like, the trigger tr is outputted, and the similar operation to that at the time of the music change is done.

That is, roughly describing, a volume correction amount (gain of a correction amplifier) is determined depending on the signal level of the head part (that is, initial part of voice information) at the time of the music change (that is, setting of initial volume correction amount). Then, if the maximum signal level of the corresponding music is updated, the volume correction amount is updated (the gain of the correction amplifier is lowered). That is, this is an operation of maintaining the volume correction amount until the maximum signal level of the corresponding music is updated (maintaining the gain of the correction amplifier).

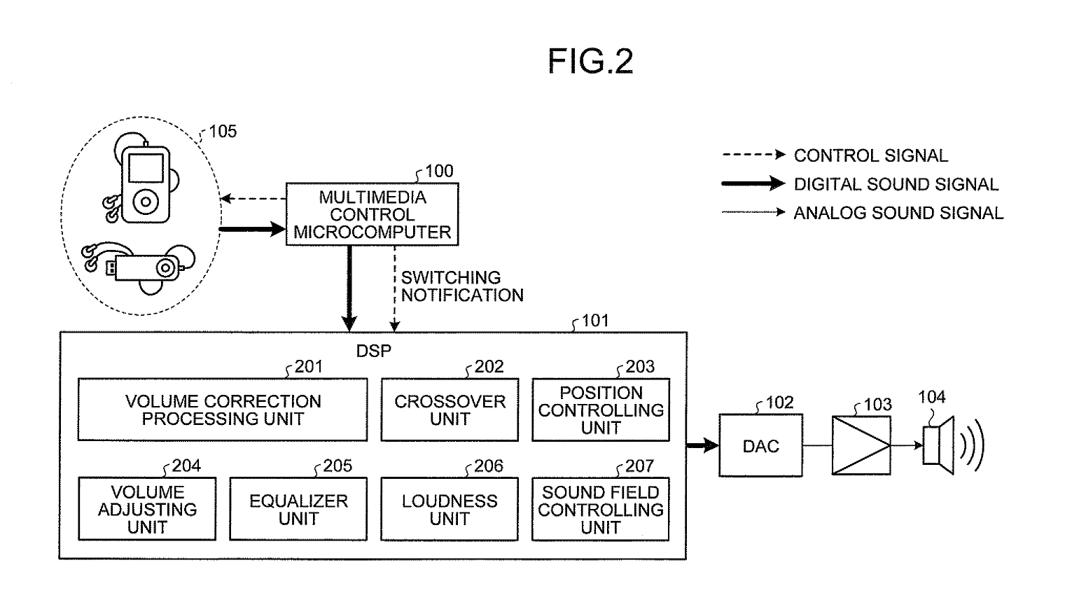

Next, main components of the volume correction in the sound equipment of the embodiment will be described. Also, the overview of the sound equipment will be described later. FIG. 2 is a configuration diagram illustrating main components of the volume correction. Also, in FIG. 2, a control signal is indicated by a dotted line, a digital sound signal is indicated by a thick line, and an analog sound signal is indicated by a thin line, respectively.

A multimedia control microcomputer 100 is a microcomputer that controls an overall operation of sound equipment. The multimedia control microcomputer 100 includes a CPU (Central Processing Unit), RAM (Random Access Memory), ROM (Read Only Memory), and the like, and performs a variety of processing according to a program stored in memory.

In particular, upon the volume correction control, the multimedia control microcomputer 100 receives a signal from a portable music player (USB memory audio) 105, and detects a change in playing music, based on a music number or the like included in the corresponding signal and also based on volume level data to be described later (silent interval determined from the volume level data). Also, the multimedia control microcomputer 100 outputs sound data inputted from the portable music player (USB memory audio) 105 to a DSP (Digital Signal Processor) 101, without especially processing.

The DSP 101 is a digital signal processor, a so-called microcomputer specialized in arithmetic processing of a sound signal or the like, and performs arithmetic processing on a sound signal from the multimedia control microcomputer 100 according to set programs, parameters (operation coefficients or the like), or the like. If main processing is expressed as processing blocks, as illustrated in FIG. 2, a volume correction processing unit 201, a crossover unit 202, a position controlling unit 203, a volume adjusting unit 204, an equalizer unit 205, a loudness unit 206, and a sound field controlling unit 207 are provided.

The volume correction processing unit 201 is a part that performs a volume correction processing according to a signal level of music, and details will be described later. Also, the crossover unit 202 adjusts the degree of separation of left and right channel signals. For example, the crossover unit 202 performs a processing to mix the left and right channel signals according to a user's stereo intensity adjustment manipulation. The position controlling unit 203 is a function mounted on, especially, a car audio. The position controlling unit 203 performs sound reproduction control suitable for a seating state by adjusting a level, phase or the like of a signal outputted from each speaker according to a crew's seating state on each seat.

The volume adjusting unit 204 adjusts the level of the sound signal according to a user's volume adjustment manipulation. The volume adjusting unit 204 determines an amplification factor of an amplifier according to a user's volume adjustment amount, regardless of the level of the input sound signal, (the DSP 101 integrates a coefficient corresponding to the user's volume adjustment amount into a digital value of the sound signal). The equalizer unit 205 adjusts a frequency characteristic of the sound signal. The equalizer unit 205 amplifies a signal of each frequency band by each amplification factor according to a user's tone adjustment amount (gain adjustment amount at each frequency band).

The loudness unit 206 amplifies signals of a low frequency region and a radio frequency region of the sound signal by an amplification factor corresponding to a user's volume adjustment manipulation. The sound field controlling unit 207 performs an additional processing on a reverberant sound of the sound signal, and performs pseudo music reproduction in the space, for example, a concert hall. The sound field controlling unit 207 realizes pseudo sound field by delay, amplification and addition processing or the like of the sound signal.

A DAC 102 is a digital-analog converter, and is a circuit that converts the digital sound signal processed in the DSP 101 into an analog sound signal. An AMP 103 is a power amplifier that amplifies the analog sound signal from the DAC 102 and outputs it from a speaker 104, and includes transistors or the like.

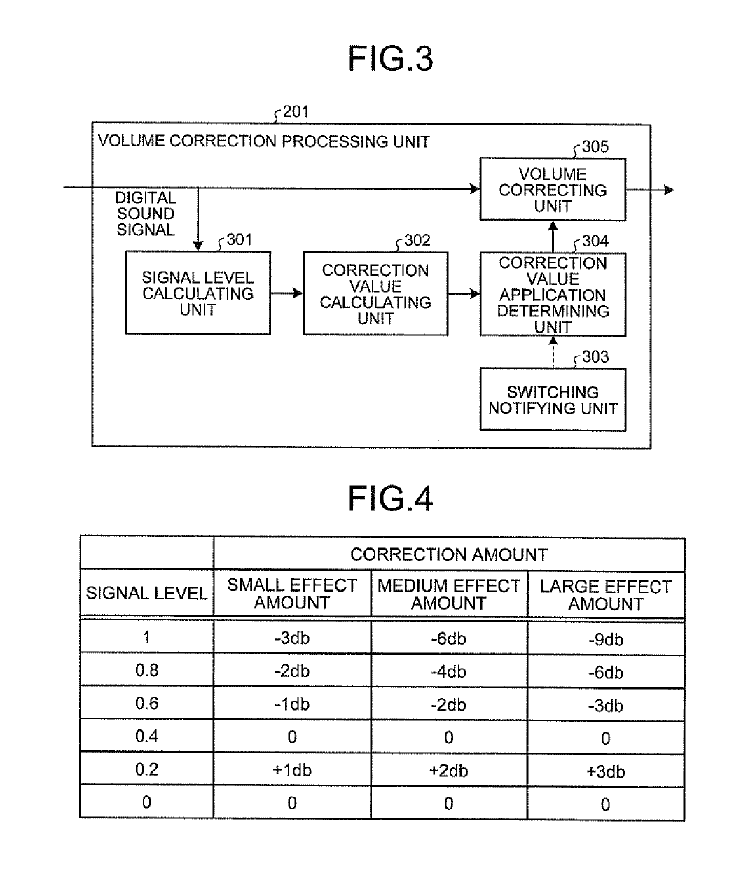

Next, the configuration of the volume correction processing unit 201 will be described. FIG. 3 is a block diagram illustrating the configuration of the volume correction processing unit 201, and represents the processing of the DSP 101 as processing blocks.

A signal level calculating unit 301 calculates a signal level of an input sound signal. In other words, a signal level of sound content or voice information is sequentially detected with the reproduction. The specific processing is a moving average processing (that is, filtering processing of the voice information) of the input sound signal (digital value). In the embodiment, a moving average processing of different time constant (averaging period, and appropriate setting of a weight of each value in the corresponding period) is performed, and also, a processing of weighting each moving average value is performed (an amplification by a different gain (integration by a different coefficient) is performed). Then, a processing of selecting and determining a maximum value of the processing value as a signal level is performed. Also, by enabling the time constant to be set by a user's manipulation, a volume correction may be performed at a response rate desired by the user.

A correction value calculating unit 302 calculates the correction value of the sound signal, that is, the gain of the amplification processing for the volume correction of the sound signal (in other words, a volume correction amount update value is derived, or an adjustment value corresponding to the maximum value is calculated). In the case of the embodiment, the calculation is a calculating method using a table, that is, stores a table corresponding to a signal level and a correction value in memory, and calculates the correction value used to select and control the correction value from the table, based on a signal level calculated in the signal level calculating unit 301.

FIG. 4 is a diagram illustrating an example of the table, and the correction value (gain of the correction amplifier) corresponding to the signal level is recorded. In the case of the embodiment, the correction value is recorded at each correction strength designated by the user (user designates the degree of the volume correction effect by the manipulation of the manipulating unit, in this example, three stages: large, medium, and small). In this configuration, the volume correction is performed at the influence rate of the correction desired by the user. Also, a method of calculating the correction value by storing a calculation formula in which the signal levels are parameters in memory, and applying the signal level calculated in the signal level calculating unit 301 to the calculation may be applied.

A switching notifying unit 303 performs a correction reset processing, based on a music change (at the time of power on, a source (sound source) switching is also included). In the embodiment, the multimedia control microcomputer 100 detects the music switching, the source switching, the power on, or the like, and outputs a music switching signal (volume correction processing trigger) to the DSP 101. The switching notifying unit 303 performs a processing of resetting the correction value (changing the correction value to the initial correction value GD), based on the corresponding trigger signal.

Also, the calculated signal level value of the signal level calculating unit 301 is outputted to the multimedia control microprocessor 100, and the multimedia control microprocessor 100 determines the music change by the silent interval (period of time during which the signal level value is in a state lower than a level recognized as the silence is continued), based on the signal level value (for example, if the silent interval is continued for 2 seconds, it is determined as the music change). In this case, the corresponding trigger signal is also outputted to the switching notifying unit 303. This processing is especially effective when reproducing a broadcasting (radio, television) having no clear music change signal, or the like.

A correction value application determining unit 304 determines whether to use the correction value (that is, the derived volume correction amount update value, the correction value corresponding to the calculated maximum value) to the volume correction, that is, whether to process the sound signal at the calculated gain. The correction value application determining unit 304 determines the application of the volume correction by a user's correction OFF manipulation, the detection of an abnormal correction value due to noise or the like (input signal level detection value), or the like, and also performs a reset processing according to the music change.

Specifically, the detected signal level is compared with the maximum value of the signal level retained in the internal memory so far. If the detected signal level exceeds the maximum value, it is determined whether the volume correction by the correction value is required (that is, the update of the volume correction amount and the maximum value of the internal memory is required) and, if not exceeding, volume correction by the correction value is not required (that is, whether to maintain the volume correction amount and the maximum value of the internal memory) is determined.

In other words, if the control by the correction value further lowers the volume than the control by the volume correction amount set so far (for example, the above-described initial volume correction amount), the volume correction amount so far is updated with the correction value.

Also, in the case where the maximum value of the internal memory is updated by including the correction value calculating unit 302 within the correction value application determining unit 304 and undergoing the comparison between the detected signal level and the maximum value of the signal level retained in the internal memory, the correction value calculating unit 302 may determine the gain from the taken maximum value.

A volume correcting unit 305 amplifies the sound signal at the determined gain corresponding to the above-described correction amplifier. Also, although not illustrated, the above-described correction value calculating unit 302, the correction value application determining unit 304, and the volume correcting unit 305 adjust the level of the sound signal of the sound content, and in other words, function as a level adjusting unit.

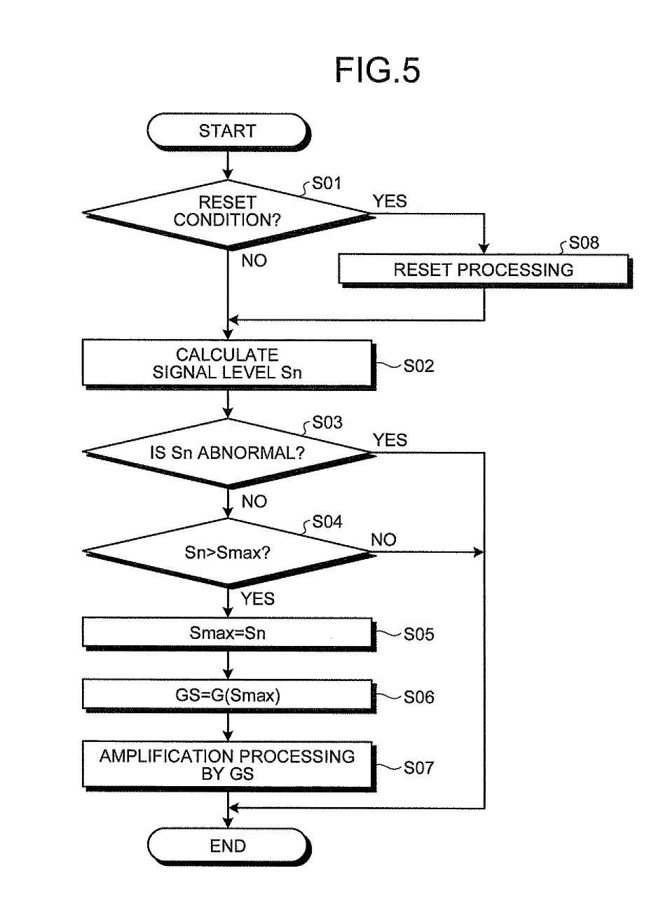

Till now, the processing contents of the volume correction processing unit 201 realized by the processing of the DSP 101 have been described with reference to the processing block diagram. However, the flow of the processing performed by the DSP 101 will also be described with reference to a flow chart. FIG. 5 is a flow chart illustrating a volume correction processing performed by the DSP 101.

Also, in the embodiment, although the processing is performed by the DSP 101, the multimedia control microcomputer 100 and the DSP 101 may share the processing while performing necessary communications (share a processing of performing the processing contents each is good at). Also, the processing is repetitively performed during the volume correction processing operation (during the reproduction of the music or the like, the case where the user sets the volume correction operation to an ON state, or the like).

Step S01 is a processing of determining whether or not it is a reset state. If a reset condition (switching of sound content, or the like) is satisfied, the processing proceeds to step S08. If there is no reset condition, the processing proceeds to a processing of S02. Step S08 is a reset processing of setting a maximum value Smax of a signal level retained in the internal memory to 0, and performs a resetting, such as setting a correction value (amplification factor of the amplifier: gain GS) to an initial value (set value), or the like. Also, the gain GS is an appropriate value obtained by an experiment or the like and, for example, a gain 0 (output of the input signal as it is) or the like is set. Also, if the gain GS is a positive value, the signal is amplified. However, if the gain GS is a negative value, the signal is attenuated.

Step S02 calculates a signal level Sn from the input sound signal and proceeds to a processing of step S03. The corresponding processing of the embodiment performs a moving average processing (that is, filtering) through two types of filters having different time constants. A larger signal level within the processing result is selected as the signal level Sn. Also, after the filtering processing, an appropriate weighting processing (integration by weighting factor) is performed on each filtering signal. This processing is performed for an appropriate volume correction to both music having a rapid volume change and music having a gradual volume change. Each weighting factor may be set to an appropriate value, based on an experiment or the like, so as to perform an appropriate volume correction.

Step S03 determines an abnormality of the calculated signal level Sn. If abnormal, the processing is ended. If not abnormal, the processing proceeds to a processing of step S04. For example, if the signal level Sn is an abnormally large value, it is determined as abnormal, and the processing is ended.

Step S04 determines whether the calculated signal level Sn is larger than a maximum signal level Smax in the stored corresponding music. If the signal level Sn is larger than the maximum signal level Smax in the corresponding music, the processing proceeds to step S05. If not larger, the processing is ended. Step S05 updates the maximum signal level Smax with the signal level Sn (signal level exceeding the maximum signal level Smax), and the processing proceeds to a processing of step S06.

Step S06 calculates the amplification factor (gain) of the amplifier, based on the updated maximum signal level Smax, and sets the calculated amplification factor as an amplifier control value. Then, the processing proceeds to step S07. Step S06 is a processing of setting and recording the amplification factor (gain), calculated by a calculation formula in which the maximum signal level Smax is set as a parameter, a table processing in which the maximum signal level. Smax is set as a selection key, or the like, as the amplifier control value.

Also, although not represented in the flow chart, in step S06, in the case where a reset processing is present (the case of setting an initial gain at the time of the music change), when the signal level is lower than a predetermined level (abnormal lower level), a fade-in state appearing frequently at an intro part of the music is determined, and the signal level of the music itself is estimated as an average signal level. That is, the gain is set to a gain value (for example, gain 0) corresponding to the average signal level.

Step S07 controls the amplification factor of the amplifier by the control gain GS, and the processing is ended. Step S07 is a processing of outputting the set and recorded amplifier control value as a control signal (if necessary, converted into a signal form suitable for control (for example, analog value)) to the amplifier.

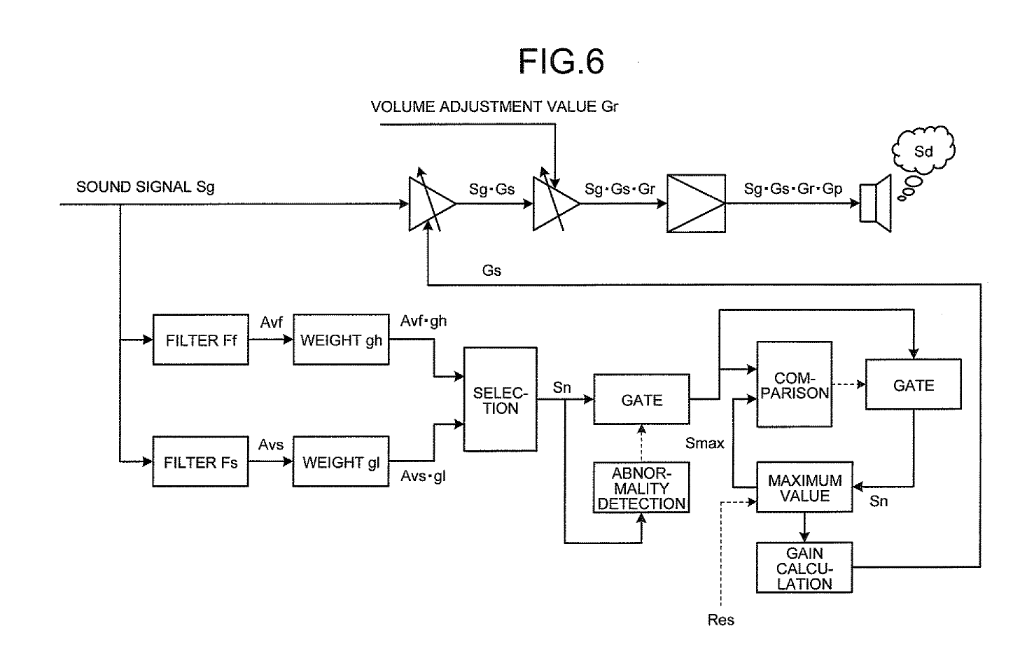

Next, a transition of the input sound signal by the above-described processing of the DSP 101 will be descried with reference to FIG. 6 that is a diagram illustrating a signal transition.

An inputted sound signal Sg has signal level values Avf and Avs by two types of moving average processing filters Ff and Fs having different time constants. Each signal level value Avf and Avs has weighted signal level values Avf.gh and Avs.gl to which weighting processing is performed. In these weighted signal level values Avf.gh and Avs.gl, a larger value becomes a signal level Sn for the selected gain calculation.

An abnormal value determination is performed and, if normal, the signal level Sn for the gain calculation is compared with the stored maximum signal level Smax. As a result of the comparison, if the signal level Sn for new gain calculation is higher than the previous maximum signal level Smax, the stored value of the maximum signal level Smax is updated with the signal level Sn for the new gain calculation. The gain Gs for the correction amplifier is calculated based on the maximum signal level Smax.

The sound signal Sg is amplified based on the gain Gs to become a correction sound signal Sg.Gs. The volume-corrected correction sound signal Sg.Gs is amplified by a preamplifier at an amplification factor Gr of a volume adjustment value based on a user's manipulation (Sg.Gs.Gr), is also amplified at a fixed amplification factor Gp by a power amplifier of a fixed amplification factor, and thus, becomes an output sound signal Sg.Gs.Gr.Gp. The output sound signal Sg.Gs.Gr.Gp is outputted from a speaker as a sound signal Sd.

Also, if a reset signal Res is inputted by the music change or the like, the maximum signal level Smax is reset (0), the gain Gs has a gain value based on the maximum signal level Smax at the time of resetting.

As described above, as the reproduction of the music is progressed, the maximum signal level of the corresponding music is calculated (updated), and the volume correction of the sound signals of the music is performed according to the maximum signal level. Since the volume correction may be achieved without previously detecting the signal levels of the entire music, the volume correction may be performed quickly. Also, since the volume correction is based on the maximum signal level, the processing is relatively simply performed, and the load of the processing devices (DSP or CPU) may be reduced, thus contributing to low costs or the like.

[Regarding Detailed Functions]

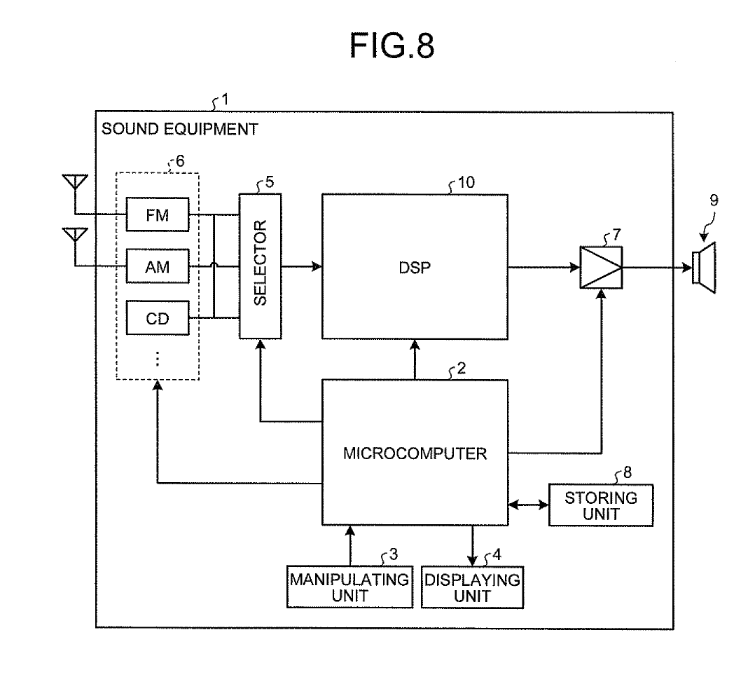

Next, an embodiment will be described concretely and in detail with reference to the accompanying drawings, especially focusing on characteristic parts thereof. Also, in the following, the outline of these characteristic parts will be described with reference to FIGS. 7A to 7C, and then, details of the sound equipment to which the example of the volume correcting method is applied, the volume correcting apparatus, and the volume correcting method will be described with reference to FIGS. 8 to 15.

First, a brief overview of the example of the volume correcting method will be described with reference to FIGS. 7A to 7C. FIG. 7A is a diagram illustrating an outline of calculating a signal level value of a sound signal. FIG. 7B is a diagram illustrating a difference in characteristics due to a difference in averaging time. FIG. 7C is a diagram illustrating a brief overview of an example of the volume correcting method.

As illustrated in FIG. 7A, the signal level value of the sound signal often uses a signal level average value of the sound signal averaged through an integration circuit (corresponding to the above-described integration filter).

Also, the averaging through such the integration circuit may obtain signal level average values of different characteristics by changing an averaging time (hereinafter, referred to as “time constant”) given to the integration circuit. In the case where the integration circuit is realized by an arithmetic processing, an appropriate integration circuit may be obtained by setting the weighting factor to an appropriate value by using a moving average processing or the like.

For example, as illustrated in FIG. 7B, the time constant is discriminated into two types of “short” and “long”. Herein, the “short” time constant is represented that the averaging period of the sound signal is short (average over the short period of time). Therefore, the signal level average value obtained through the integration circuit well represents “rapid signal” greatly varying at the “short” interval (see “adaptable to the rapid signal” in the drawing).

Also, as the “rapid signal”, there have been known music genres, such as “rock”, which include a lot of high frequencies in the audible band and have a speedy tempo.

On the other hand, the “long” time interval represents that the averaging period of the sound signal is long (average over the long period of time). Therefore, the signal level average value obtained through the integration circuit well represents “gradual signal” gradually varying at the “long” interval (see “adaptable to the gradual signal” in the drawing).

Also, as the “gradual signal”, there have been known music genres, such as “classic”, which include a lot of low frequencies in the audible band and have a slow tempo.

Due to the difference of these time constants, the difference in the characteristics of the signal level average values may be used according to the difference of the reproduction band the music has and the diversity of the variation. Therefore, in the example of the volume correcting method, a plurality of integration circuits having different time constants are provided, and each integration circuit inputs a sound signal of a band component corresponding to the time constant.

Also, the difference in the characteristic of the signal level average value obtained by changing the time constant may be used. The weighting is performed according to the difference corresponding to the signal level average value outputted from each integration circuit.

Specifically, as illustrated in FIG. 7C, a plurality of integration circuits including a first integration circuit 16a having a “short” time constant and a second integration circuit 16b having a “long” time constant are provided in a signal level calculating unit 16 corresponding to the signal level calculating unit 301 of the volume correction processing unit 201 inside the above-described DSP 101 (see FIG. 3). Each integration circuit inputs a different sound signal of a band component (see

FIG. 7C, “sound signal of band a” and “sound signal of band b”).

With respect to the signal level average value outputted by the first integration circuit 16a, the weighting is performed by a weighting factor corresponding to the characteristic in an amplifier 16c (that is, amplification is performed with the amplification degree corresponding to the weighting factor). Also, with respect to the signal level average value outputted by the second integration circuit 16b, the weighting is performed by a weighting factor corresponding to the characteristic in an amplifier 16d (that is, amplification is performed with the amplification degree corresponding to the weighting factor).

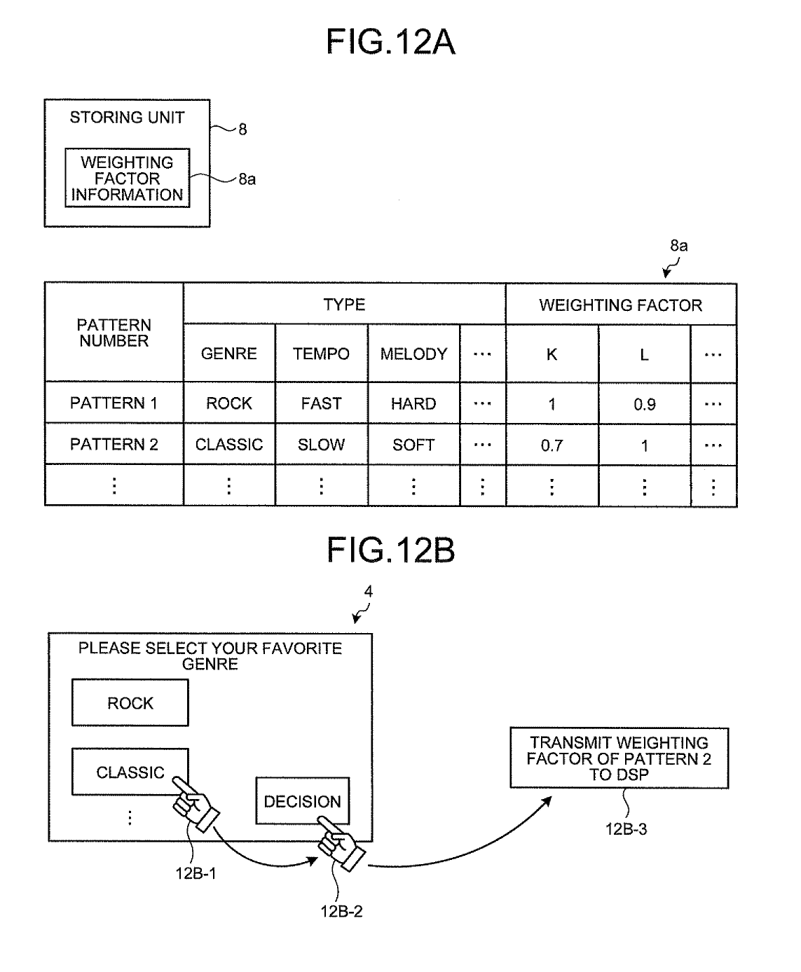

Herein, each weighting factor may use a value of a pattern of a combination of predetermined weighting factors previously determined based on the music genre, the user's preference, or the like. Also, details of such points will be described later with reference to FIGS. 12A and 12B.

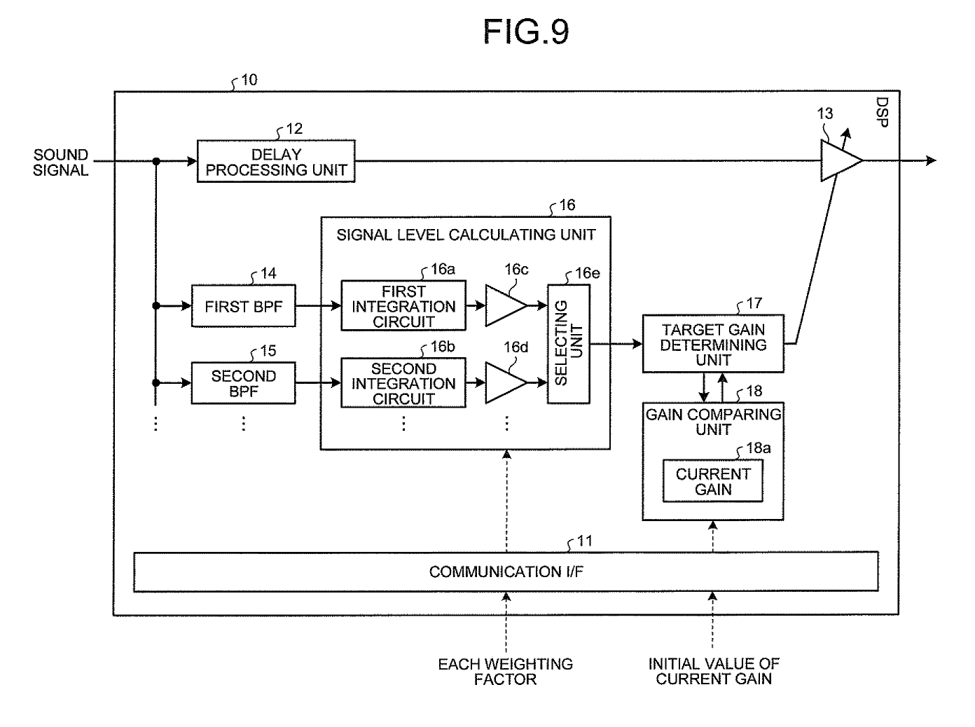

A representative value is selected in a selecting unit 16e, based on each signal level average value after the weighting, and a gain used for volume correction is determined from such a representative value. Also, details of each processing unit illustrated in FIG. 7C will be described later with reference to FIG. 9.

Therefore, in the example of the volume correcting method, a plurality of integration circuits having different time constants, considering the difference in the characteristics of the signal level average values obtained by changing the time constant. Then, each inputs the sound signal of the band component corresponding to the time constant. Also, with respect to the output value of each integration circuit, the weighting is performed based on the music genre, the user's preference, or the like.

Therefore, since the example of the volume correcting method may a representative value of a signal level corresponding to the difference of the reproduction band of a wide variety of music and the difference of the variation, an appropriate gain may be calculated. A volume may be corrected such that an uncomfortable feeling is not given to listeners. Also, since the weighting is performed based on the music genre, the user's preference, or the like, the volume correction may be performed according to the listener's preference.

Hereinafter, embodiments of sound equipment, a volume correcting apparatus, and a volume correcting method, to which the volume correcting method described with reference to FIGS. 7A to 7C is applied, will also be described in detail.

FIG. 8 is a diagram illustrating a configuration example of sound equipment 1. As illustrated in FIG. 8, the sound equipment 1 includes a microcomputer 2, a manipulating unit 3, a displaying unit 4, a selector 5, a sound source 6, a main amplifier 7, a storing unit 8, and a DSP 10. Also, a speaker 9 is disposed outside. Also, in the case of an automotive purpose, the sound equipment 1 is located at a position such as a dash board or the like of an automobile and configured to reproduce a desired sound by outputting a sound signal to the speaker 9 installed at a door or the like of the automobile.

The DSP 10 corresponding to the DSP 101 (see FIG. 2) is a microprocessor that performs the volume correction of the sound signal of the sound source 6 inputted through the selector 5, and a so-called digital signal processor designed to specialize in arithmetic processing such that high-speed arithmetic processing is possible. Also, the DSP 10 outputs the volume-corrected sound signal to the main amplifier 7, which will be described later.

Also, the DSP 10 may perform a variety of digital signal processing related to the sound signal, such as a sound quality correction processing (frequency characteristic correction processing), a volume adjustment processing based on a user's volume adjustment manipulation, or the like, as well as a volume correction. However, in the following, the description will be made focusing on the function of correcting the volume. Therefore, the DSP 10 as shown below may correspond to the volume correction processing unit 201 illustrated in FIG. 3. Details of the DSP 10 will be described later with reference to FIG. 9.

The microcomputer 2 corresponding to the multimedia control microcomputer 100 (see FIG. 2) is a central processing unit that controls the entire sound equipment 1. Also, the microcomputer 2 may be configured in a plurality of units differentiated for each function. In the embodiment, the microcomputer 2 configured in a single unit will be described.

The manipulating unit 3 is a manipulating component that receives a user's input manipulation. The manipulating unit includes software components such as a button displayed on the displaying unit 4, which will be described later, as well as hardware components such as a dial or a button.

The displaying unit 4 is an output device configured by a liquid crystal device or the like that displays display information to the user. The selector 5 is an output device that selects a specific sound source from the sound source 6, which will be described later, based on a switching request from the microcomputer 2, and outputs a sound signal of the selected sound source to the DSP 10. The selector 5 is configured by a switching circuit (IC) using a switching transistor or the like.

The sound source 6 is a sound device group of an FM tuner, an AM tuner, a CD player, or a portable music player 105 (see FIG. 2), and the like. The sound source 6 is controlled by the microcomputer 2. The main amplifier 7 is a device that amplifies the sound signal inputted from the DSP 10 at a predetermined amplification factor. Also, the main amplifier 7 corresponding to the AMP 103 (see FIG. 2) outputs the amplified sound signal to the speaker 9.

The speaker 9 corresponding to the speaker 104 (see FIG. 2) is an output device that outputs a sound by converting the sound signal (electrical signal) inputted from the main amplifier 7 into a physical vibration. Also, in FIG. 8, although one speaker 9 is illustrated, the number of actual devices is not limited thereto. Therefore, the speaker 9 may be a mono speaker or a stereo speaker.

The storing unit 8 is a storing unit configured by a storing device such as a hard disc or nonvolatile memory (flash memory, RAM backed up by a power supply, or the like), and stores a variety of information related to the volume correction such as the weighting factor information 8a (which will be described later with reference to FIG. 12A) or the like.

Next, details of the DSP 10 will be described with reference to FIG. 9. FIG. 9 is a diagram illustrating a configuration example of the processing block of the DSP 10. Also, FIG. 9 illustrates only constituent elements necessary to describe the characteristics of the DSP 10, and general constituent elements are not described. Also, in the following, although each constituent element is described as a processing block, it is not limited to a structure in which there exists a configuration that performs each independent processing within the DSP 10. For example, it was said that the calculating unit sequentially realizes each function (processing) by the execution of the program and it may be realized by so-called software.

As illustrated in FIG. 9, the DSP 10 includes a communication I/F (interface) 11, a delay processing unit 12, an amplifier 13, a BPF group including a first BPF (Band-Pass Filter) 14 and a second BPF 15, a signal level calculating unit 16, a target gain determining unit 17, and a gain comparing unit 18. Also, the BPF group is an example for realizing a bandwidth limitation. If a bandwidth limitation is possible, it is not necessary to specialize in the BPF.

Also, the signal level calculating unit 16 further includes the first integration circuit 16a, the second integration circuit 16b, the amplifier 16c, the amplifier 16d, and the selecting unit 16e.

Also, as illustrated in FIG. 9, the sound signal inputted to the DSP 10 is branched to a dual-system at a preceding stage of the delay processing unit 12. In the following, the case of showing the system passing through the delay processing unit 12 is described as a “direct system”, and the case of showing the other system is described as a “correcting system”.

The communication I/F 11 is a communication device that performs communication with the microcomputer 2. A “weighting factor”, a “current gain initial value”, or the like, which will be described later, is inputted from the microcomputer 2 through the communication I/F 11.

The delay processing unit 12 is a processing block that delays the sound signal inputted from the selector 5 by a predetermined period of time, and outputs the delayed sound signal to the amplifier 13. Such a delay is performed such that the sound signal inputted from the selector 5 is amplified in the amplifier 13, based on the target gain corresponding to its own signal level, in order to synchronize the sound signal inputted from the selector 5 and the target gain outputted from the target gain determining unit 17.

The amplifier 13 is a processing block that amplifies the sound signal inputted from the delay processing unit 12 according to the target gain inputted from the target gain determining unit 17. That is, the amplifier 13 corrects the signal level of the sound signal inputted from the delay processing unit 12 by using the target gain inputted from the target gain determining unit 17. Also, the amplifier 13 outputs such a corrected sound signal to the main amplifier 7.

The BPF group including the first BPF 14 and the second BPF 15 is a filter that passes only a predetermined frequency band of the sound signal inputted from the selector 5. Also, in the embodiment, a configuration example including at least two BPFs of the first BPF 14 and the second BPF 15 is illustrated.

The first BPF 14 is a filter that mainly passes a radio frequency band. Also, the first BPF 14 outputs the sound signal of the passed radio frequency band to the first integration circuit 16a. Likewise, the second BPF 15 is a filter that mainly passes a low frequency band. Also, the second BPF 15 outputs the sound signal of the passed low frequency band to the second integration circuit 16b.

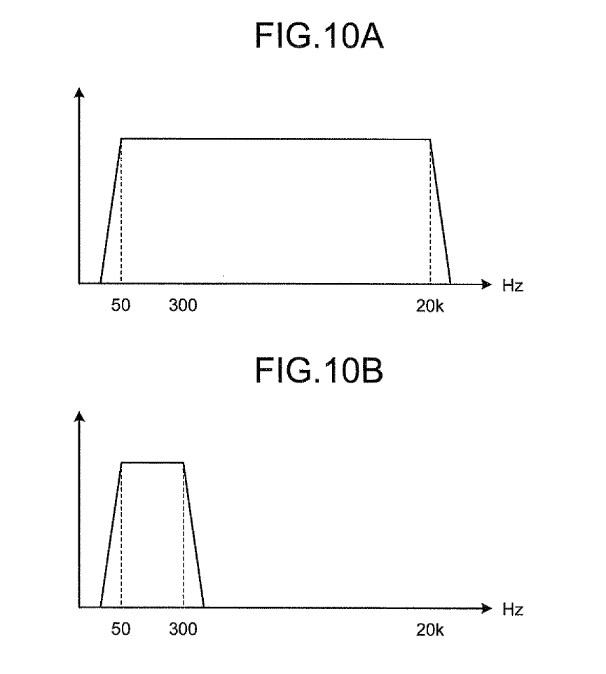

Herein, in the embodiment, the “radio frequency band” and the “low frequency band” will be described with reference to FIGS. 10A and 10B. FIG. 10 is a diagram illustrating the pass band of the first BPF 14, and FIG. 10B is a diagram illustrating the pass band of the second BPF 15.

For example, as illustrated in FIG. 10A, the first BPF 14 passes the signal of the band of 50 Hz to 20 kHz and does not pass the signal of the other band. In other words, the first BPF 14 outputs only the signals of almost all bands of so-called human audible band to the first integration circuit 16a.

Also, as illustrated in FIG. 10B, the second BPF 15 passes the signal of the band of 50 Hz to 300 Hz, and does not pass the signal of the other band. In other words, the second BPF 15 mainly outputs only the sound signal of the low frequency band to the second integration circuit 16b.

In the following, for comparison of description, the signal corresponding to the pass band of the first BPF 14 illustrated in FIG. 10A may be described as “radio frequency signal” or “radio frequency”, and the signal corresponding to the pass band of the second BPF 15 illustrated in FIG. 10B may be described as “low frequency signal” or “low frequency”.

Also, as illustrated in FIGS. 10A and 10B, the pass bands the first BPF 14 and the second BPF 15 may be overlapped, for example, as illustrated in 50 Hz to 300 Hz in the drawing.

Returning back to the description of FIG. 9, the signal level calculating unit 16 will be described.

The signal level calculating unit 16 is a processing block that calculates the representative value of the signal level of the sound signal inputted from each BPF, such as the first BPF 14 or the second BPF 15.

Also, such a representative value is a maximum value of each signal level average value calculated with respect to each system corresponding to each BPF.

The first integration circuit 16a averages the radio frequency signal inputted from the first BPF 14 at a short time constant suitable for the variation of the rapid signal, and outputs the averaged signal (first average value) to the amplifier 16c. Also, since the signal is averaged at the short time constant, the signal shows the signal level quickly following the signal.

The second integration circuit 16b averages the low frequency signal inputted from the second BPF 15 at a long time constant suitable for the variation of the gradual signal, and outputs the averaged signal (second average value) to the amplifier 16d. Also, since the signal is averaged at the long time constant, the signal shows the signal level gradually following the signal.

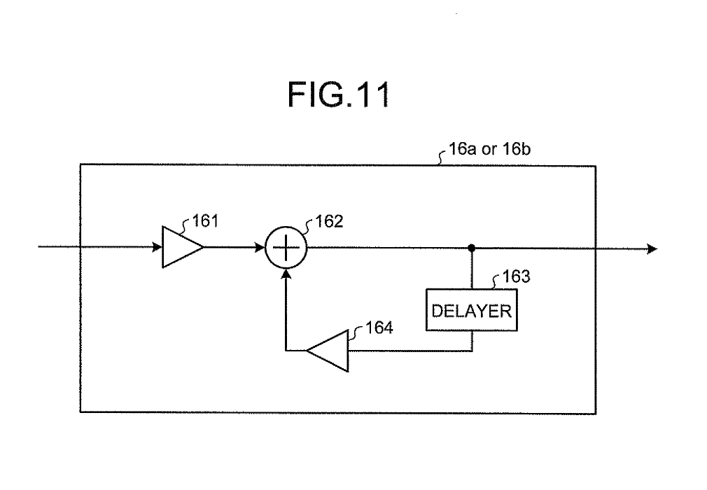

Herein, the configuration example of the first integration circuit 16a and the second integration circuit 16b will be described with reference to FIG. 11. FIG. 11 is a diagram illustrating the configuration example of the first integration circuit 16a and the second integration circuit 16b.

As illustrated in FIG. 11, the first integration circuit 16a and the second integration circuit 16b include an amplifier 161, an adder 162, a delayer 163, and an amplifier 164. The amplifier 161 amplifies the signal of the inputted sound signal at a predetermined amplification factor.

The signal amplified by the amplifier 161 is delayed by a predetermined period of time by the delayer 163, and then is amplified at a predetermined amplification factor (amplification factor<1:attenuation) by the amplifier 164. The signal level amplified by the amplifier 164 is added in the adder 162 and outputted.

Herein, the first integration circuit 16a and the second integration circuit 16b are different in the predetermined amplification factors of the amplifier 164. That is, the first integration circuit 16a includes the amplifier 164 of a short time constant as compared to the second integration circuit 16b (by decreasing the amplification factor, the influence of the previous signal is decreased). The second integration circuit 16b includes the amplifier 164 of a long time constant as compared to the first integration circuit 16a (by increasing the amplification factor, the influence of the previous signal is increased).

Also, in the embodiment, although the time constant is simply divided into two types of “short” and “long” and the two integration circuits of the first integration circuit 16a and the second integration circuit 16b have been exemplarily described, the time constant may be divided into three or more steps, and the corresponding three or more integration circuits may be installed.

For example, an integration circuit of a small time constant of units of μ a second may be further provided. If a large signal level value is outputted by the integration circuit of such a time constant, it is determined as noise by signal discontinuity, and a processing such as disabling a subsequent processing may be performed.

Also, in the following, the case where the integration circuits includes two integration circuits of the first integration circuit 16a and the second integration circuit 16b will be exemplarily described.

Returning back to the description of FIG. 9, the amplifier 16c will be described. The amplifier 16c amplifies the first average value inputted from the first integration circuit 16a by a predetermined weighting factor corresponding to the first average value and then outputs to the selecting unit 16e.

Also, the amplifier 16d amplifies the second average value inputted from the second integration circuit 16b by a predetermined weighting factor corresponding to the second average value and then outputs to the selecting unit 16e.

Also, the respective weighting factors used by the amplifier 16c and the amplifier 16d are inputted from the microcomputer 2 as described above. Herein, weighting factor information 8a being information including such weighting factors will be described with reference to FIGS. 12A and 12B.

FIGS. 12A and 12B are explanatory diagrams of the weighting factor information 8a. Also, FIG. 12A illustrates a setting example of the weighting factor information 8a, and FIG. 12B illustrates a manipulation example related to transmission of the weighting factor to the DSP 10.

As illustrated in FIG. 12A, the weighting factor information 8a is information related to the volume correction weighting factor stored in the storing unit 8 included in the above-described sound equipment 1, and is stored in association with a “pattern number” item, a “type” item, and a “weighting factor” item.

The “pattern number” item is an item of pattern numbers assigned to weighting factor combination patterns for each system of the integration circuit. The weighting factor information 8a may manage a relation of each piece of information as the record of such pattern numbers. In such a case, the pattern number is a basic key for searching each record of the weighting factor information 8a.

The “type” item is an item that stores each type being a secondary key for each record search. Also, FIG. 12A illustrates an example in which the “type” item further includes a “genre” item, a “tempo” item, and a “melody” item.

For example, the “genre” item is an item of information that identifies the genre of music, such as “rock” or “classic”. The “tempo” item is an item of information that identifies the tempo of music, such as “fast” or “slow”. The “melody” item is an item of information that identifies the melody of music, such as “hard” or “soft”.

Also, herein, for convenience of description, although each stored value of the “type” item is expressed as a text format, it does not limit a data format of each stored value.

The “weighting factor” item is an item of weighting factor combination for each system of the integration circuit corresponding to each pattern number. For example, FIG. 12A illustrates an example in which at least the weighting factor K of the system of the “first integration circuit” and the weighting factor L of the system of the “second integration circuit” are included in the combination patterns.

Also, the weighting factor combination may be determined according to the information of the “type” item. For example, in the case where the genre is “rock”; the tempo is “fast”; and the melody is “hard”, a lot of radio frequencies are included. Meanwhile, in the case where it is expected that a rapid sound signal is inputted, like the record of “pattern 1” illustrated in FIG. 12A, the weighting factors may be combined such that the weighting factor K corresponding to the first integration circuit 16a is relatively high “1”, and the weighting factor L corresponding to the second integration circuit 16b is relatively low “0.9”.

On the other hand, in the case where the genre is “classic”; the tempo is “slow”; and the melody is “soft” a lot of low frequencies are included. Meanwhile, in the case where it is expected that a gradual sound signal is inputted, like the record of “pattern 2”, the weighting factors may be combined such that the weighting factor K is relatively low “0.7”, and the weighting factor L is relatively high “1”.

Herein, it is assumed that the weighting factor combination pattern of “pattern 1” is already determined as default. In such a case, the microcomputer 2 reads the record having pattern number of “pattern 1” from the weighting factor information 8a of the storing unit 8 upon the initial driving of the sound equipment 1, and transmits the read record to the DSP 10.

That is, upon the initial driving of the sound equipment 1, the weighting factor of the amplifier 16c of the DSP 10 is set to “1”, and the weighting factor of the amplifier 16d is set to “0.9”.

Likewise, in the case where the weighting factor combination pattern of “pattern 2” is the default, the weighting factor of the amplifier 16c is set to “0.7”, and the weighting factor of the amplifier 16d is set to “1”.

Also, in addition to the default setting upon the initial driving of the sound equipment 1 or the like, the weighting factor combination pattern may be variably set based on the designated value designated by the user's manipulation. For example, as illustrated in FIG. 12B, a setting screen related to the volume correction, like “please select your favorite genre”, is displayed on the displaying unit 4.

In such a setting screen, as illustrated in FIG. 12B, a manipulation part (manipulation button) corresponding to the type as the above-described secondary key, like “rock” or “classic”, may be disposed.

If a “classic” is selected as the user's favorite genre (see 12B-1 in the drawing) and a “decision” button corresponding to the decision of selection is pressed down (see 12B-2 in the drawing), the microcomputer 2 may transmit the weighting factor combination pattern of “pattern 2” illustrated in FIG. 12A to the DSP 10 (see 12B-3 of FIG. 12B).

Also, although FIG. 12B illustrates the example of the setting screen on which the manipulation part corresponding to the “genre” type of FIG. 12A is disposed, it is apparent that manipulation parts corresponding to “pattern number” being the basic key and “tempo” or “melody” being other secondary keys may also be disposed.

Also, the opportunity of the variable setting of the weighting factor combination pattern is not limited to the case where there is the designated value based on the user's manipulation. For example, the variable setting of the appropriate weighting factor combination may be performed according to the change in noise during the traveling of the automobile.

This may be realized by further including a “noise frequency band” item storing a frequency band of a traveling noise in the “type” item of the weighting factor information 8a, associating and storing the weighting factor combination pattern at each frequency band, and transmitting the weighting factor combination patterns corresponding to the frequency band to the DSP 10 according to the change in the frequency band of the traveling noise collected using a microphone or the like.

However, although the description with reference to FIGS. 12A and 12B has been made about the case of setting the weighting factors of the amplifier 16c or the amplifier 16d based on the preset weighting factor information 8a, the weighting factors of the amplifier 16c and the amplifier 16d may be set without being based on such weighting factor information 8a.

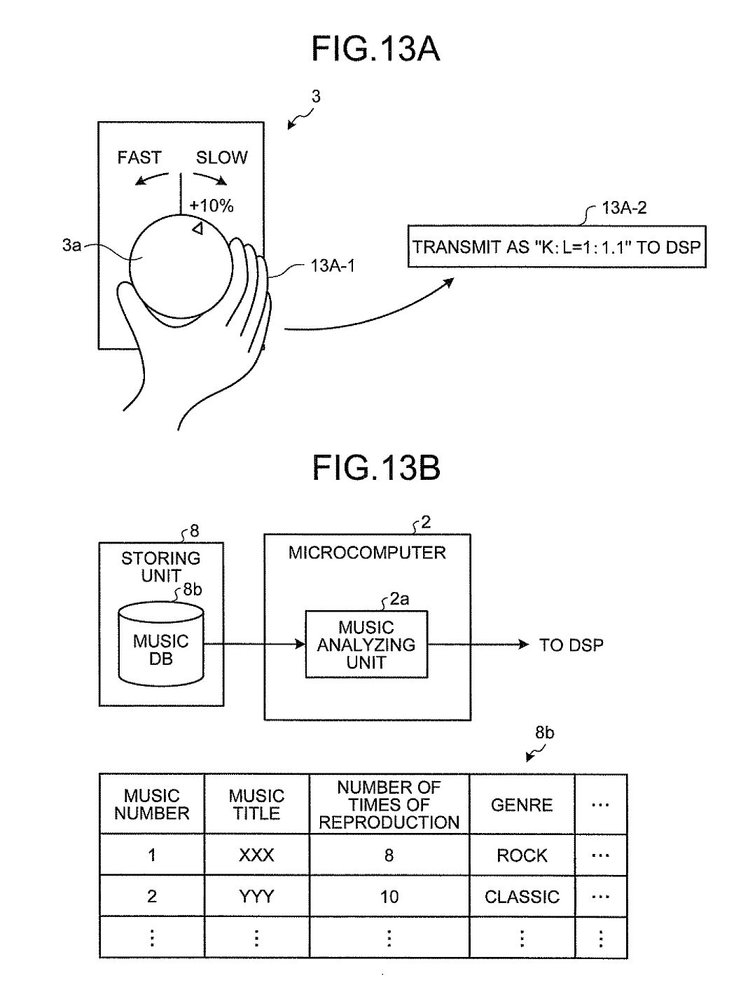

A modified example will be described with reference to FIGS. 13A and 13B. FIGS. 13A and 13B are diagrams illustrating a modified example of the weighting factor setting. Also, FIG. 13A illustrates a modified example of the weighting factor setting by the user's manipulation, and FIG. 13B illustrates a case based on a music DB 8b.

As illustrated in FIG. 13A, the sound equipment 1, for example, may include a dial 3a, which is capable of adjusting “tempo” to be closer to “fast” or “slow”, in the manipulating unit 3. Herein, a ratio (“K:L”) of the weighting factor K to the weighting factor L (see FIG. 12A) is “1:1”.

In this case, as illustrated in FIG. 13A, in the case where the user rotates the dial 3a to a position showing “+10%” closer to “slow” (see 13A-1 in the drawing), the microcomputer 2 may set the ratio of the weighting factor L to “+10%”, and may transmit to the DSP 10 as “K L”=“1:1.1” (see 13A-2 in the drawing).

The DSP 10 changes the weighting factor ratio of the amplifier 16c to the amplifier 16d to “1:1.1”, based on the notification indicating “K:L” =“1:1.1” transmitted by the microcomputer 2.

Also, as illustrated in FIG. 13B, a database related to a music reproduction history may be based on the music DB 8b. In such a case, the sound equipment 1 according to a modified example may further include a music analyzing unit 2a in the microcomputer 2.

The music DB 8b is a database that accumulates the music reproduction history. Also, the music DB 8b is frequently updated whenever one piece of music is reproduced by the microcomputer 2 or the like.

For example, as illustrated in FIG. 13B, the music DB 8b includes a “music number” item identifying music, a “music title” item storing music title, a “number of times of reproduction” item storing number of times of reproduction, and a “genre” item storing identification value of the genre of the music. Also, for example, in the case where the music data is an MP3 format, the identification value of the genre may use tag information based on format specification.

The music analyzing unit 2a analyzes the music DB 8b and determines weighting factor combination pattern transmitted to the DSP 10.

Herein, as illustrated in FIG. 13B, in the music DB 8b, the music “XXX” having the music number of “1” and the genre of “rock” is “8” in the number of times of reproduction, and the music “YYY” having the music number is “2” and the genre of “classic” is “10” in the number of times of reproduction.

In this case, in the case where there are only two pieces of music (or, only two pieces of music are used for processing), as a modified example of a weighting factor setting, the music analyzing unit 2a determines “K:L” being the weighting factor combination pattern as the reproduction ratio of a “fast” “tempo” o music to “slow” “tempo” music of “0.8:1 (=8:10)” and transmits to the DSP 10.

Also, a modified example of determining the weighting factor combination pattern, based on the aggregate result for each genre of the music registered in the music DB 8b, and transmitting to the DSP 10 is practical and effective. For example, it is assumed that “100” pieces of “rock” genre music and “70” pieces of “classic” genre music are registered in the music DB 8b.

In this case, the music analyzing unit 2a determines the above-described “K:L” as the music number ratio of “1:0.7 (=100:70)”, based on “100” that is the number of pieces of “rock” genre music corresponding to “fast” “tempo” and “70” that is the number of pieces of “classic” genre music corresponding to “slow” “tempo”, and transmits to the DSP 10.

Also, the music analyzing unit 2a frequently performs an analysis operation of the music DB 8b on a background. For example, the user may accidentally reproduce a favorite music different from an ordinary day in the mood for that day, request a ratio of genre of the played music at that day, and perform a volume correction suitable for the genre tendency of that day.

Therefore, the volume control appropriate to the user's preference may be performed by determining the weighting factor based on the aggregate result of the number of times of reproduction or the registered music.

Returning back to the description of FIG. 9, the selecting unit 16e will be described. The selecting unit 16e is a processing block that determines a maximum value of an average value of each signal level such as the first average value and the second average value or the like, to which individual weighting is performed, as a representative value of the signal level calculating unit 16, and outputs the representative value to the target gain determining unit 17.

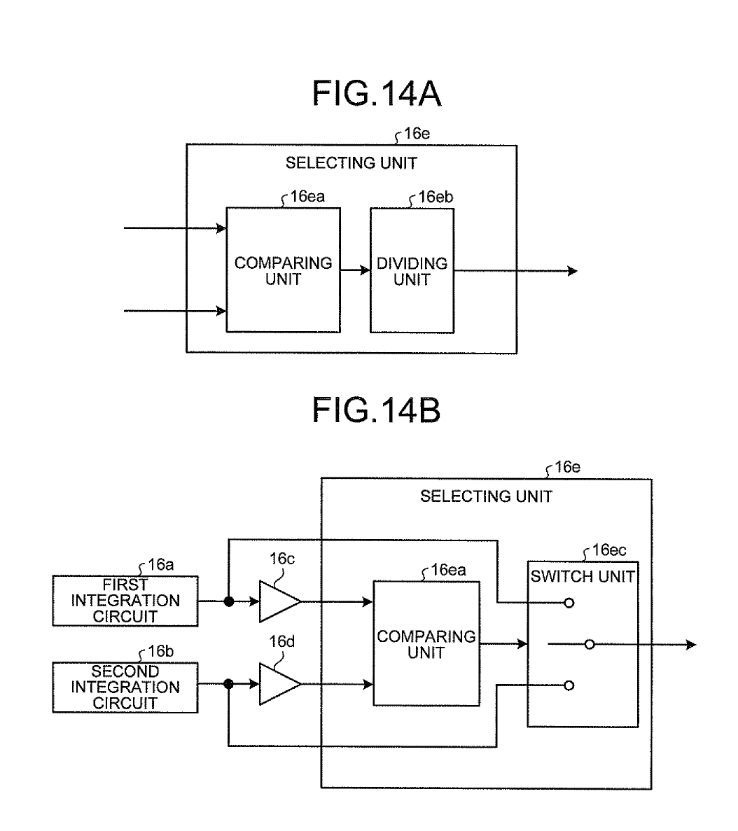

Herein, a configuration example of the selecting unit 16e will be described with reference to FIGS. 14A and 14B. FIGS. 14A and 14B are diagrams illustrating the configuration example of the selecting unit 16e. Also, FIG. 14A illustrates a first configuration example of the selecting unit 16e, and FIG. 14B illustrates a second configuration example of the selecting unit 16e.

As illustrated in FIG. 14A, the selecting unit 16e includes a comparing unit 16ea and a dividing unit 16eb. The comparing unit 16ea compares the inputted first average value and second average value through, for example, a comparator or the like, and outputs a maximum value to the dividing unit 16eb.

The dividing unit 16eb returns the maximum value inputted from the comparing unit 16ea to the unweighted value by dividing the maximum value by the weighting factor of the corresponding amplifier 16c or amplifier 16d, and outputs as the representative value. Also, the reciprocal of the weighting factor may be multiplied. Also, the maximum value outputted by the comparing unit 16ea may be outputted as the representative value as it is, without providing the dividing unit 16eb.

Also, as illustrated in FIG. 14B, the selecting unit 16e may include a comparing unit 16ea and a switch unit 16ec. The switch unit 16ec is a switch that switches the first average value of the first integration circuit 16a branched at the preceding stage of the amplifier 16c, and the second average value of the second integration circuit 16b branched at the preceding stage of the amplifier 16d.

In the configuration example 2 illustrated in FIG. 14B, the comparing unit 16ea compares the inputted first average value with the inputted second average unit, and outputs a switching instruction signal of a system selected as a maximum value to the switch unit 16ec.

The switch unit 16ec performs a switching of an input system, based on the switching instruction signal inputted from the comparing unit 16ea, and outputs the corresponding first average value or second average value as the representative value.

Returning back to the description of FIG. 9, the target gain determining unit 17 will be described. The target gain determining unit 17 corresponding to the correction value calculating unit 302 (see FIG. 3) is a processing block that determines the target gain as the volume correction “coefficient”, based on the representative value inputted from the signal level calculating unit 16, and outputs the target gain to the amplifier 13.

The gain comparing unit 18 corresponding to the correction value application determining unit 304 (see FIG. 3) is a processing block that retains a “current gain” 18a applied to the current amplifier 13 in the internal memory, compares a “target gain” inputted from the target gain determining unit 17, which will be described later, with the “current gain” 18a, and outputs the comparison result to the target gain determining unit 17.

The target gain determining unit 17 and the gain comparing unit 18 will be described in detail. First, the target gain determining unit 17 calculates a difference value between the representative value inputted from the selecting unit 16e of the signal level calculating unit 16 and a predetermined target signal level value (hereinafter, referred to as “reference level value”), and outputs the difference value to the gain comparing unit 18 as the target gain being the volume correction “amount”.

Herein, the target gain as the volume correction “amount” is an increase or decrease amount necessary to set the signal level value of the sound signal of the “direct system” to the reference level value. The current gain 18a retained by the gain comparing unit 18 also is an increase or decrease “amount”, and is an increase or decrease “amount” necessary to set the signal level maximum value of the signal of the part reproduced until the present time, while the music is being reproduced, to the reference level.

The gain comparing unit 18 compares the target gain inputted from the target gain determining unit 17 with the current gain 18a. If the target gain is smaller than the current gain 18a, the current gain 18a is maintained, and the current gain 18a is outputted to the target gain determining unit 17 as the target gain.

Also, if the target gain inputted from the target gain determining unit 17 is larger than the current gain 18a, the gain comparing unit 18 updates the current gain 18a with the target gain and outputs the target gain to the target gain determining unit 17 as it is.

The target gain determining unit 17 converts the target gain being the comparison result inputted from the gain comparing unit 18 into the target gain being “coefficient” from the target gain as the “amount”, that is, the value (gain of the amplifier) used for the volume correction processing of the DSP. For example, the reference level value is “−3 dB”, and the target gain as the “amount” is “+3 dB” (that is, deficiency of 3 dB).

In such a case, for example, the target gain determining unit 17 calculates the target gain being the “coefficient” as “10̂3/20”. The target gain determining unit 17 outputs the target gain being the calculated “coefficient” to the amplifier 13, and controls the amplifier through the operation corresponding to the target gain (multiplication of the calculated “coefficient”).

Also, as illustrated in FIG. 9, the gain comparing unit 18 resets the current gain 18a to the current gain initial value notified from the microcomputer 2 at the time of switching the sound source 6 or the music. That is, the gain comparing unit 18 is a processing block corresponding to the switching notifying unit 303 (see FIG. 3). Also, from the microcomputer 2, only the switching signal notifying such a switching may be received, and the gain comparing unit 18 may reset the current gain 18a to the fixed value.

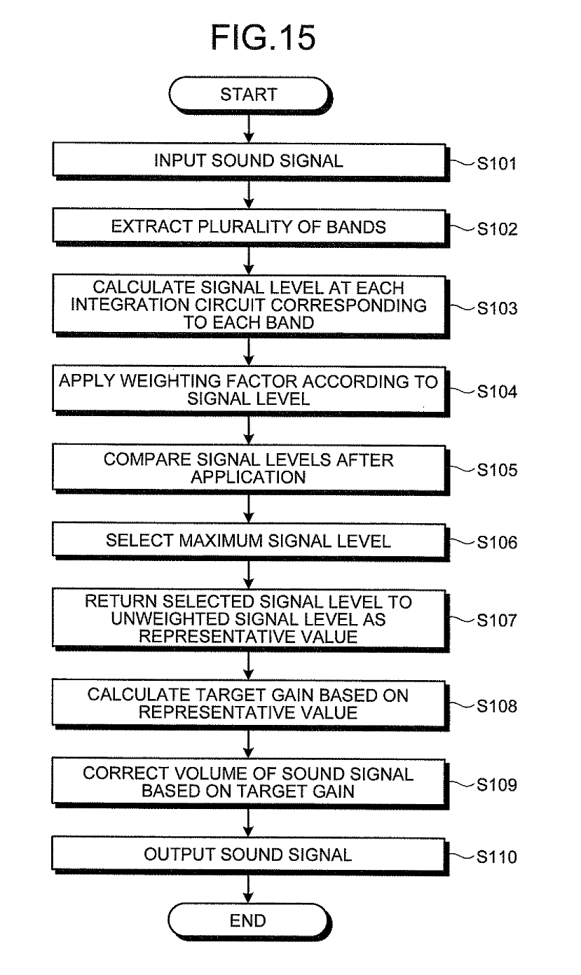

Next, the processing procedure performed by the DSP 10 will be described with reference to FIG. 15. FIG. 15 is a flow chart illustrating the processing procedure performed by the DSP 10. Also, during the reproduction operation of the sound equipment 1, in the case where the user performs the ON manipulation of the volume correction function, the processing is repetitively performed.

As illustrated in FIG. 15, the DSP 10 inputs a sound signal of the sound source 6 through the selector 5 in step S101. In the above-described “correction system”, the sound signal is divided into a plurality of bands and then extracted in step S102. Also, although not illustrated, in the above-described “direct system”, the delay processing unit 12 of the inputted sound signal is waited.

Then, the signal level calculating unit 16 calculates the signal level value at each integration circuit such as the first integration circuit 16a and the second integration circuit 16b corresponding to each band in step S103. Then, with respect to the calculated signal level value, the weighting factor previously determined at each calculation system is applied (for example, multiplication) in step S104.

Then, the signal level calculating unit 16 compares the signal level values at each calculation system after the application of the weighting factor in the selecting unit 16e in step S105, and selects the maximum signal level value in step S106.

Then, the signal level calculating unit 16 returns the signal level value selected by the selecting unit 16e to the unweighted signal level value in step S107. The returned signal level value is outputted as the representative value to the target gain determining unit 17.

Then, the target gain determining unit 17 calculates the target gain based on the representative value inputted from the signal level calculating unit 16 in step S108. A final gain is determined through comparison with the current gain 18a retained in the gain comparing unit 18 and is outputted to the amplifier 13 in step S109.

Then, the amplifier 13 performs the volume correction of the sound signal, based on the determined target gain in step S109 and outputs the sound signal to the outside (main amplifier 7) in step S110.

As described above, in the embodiment, the sound equipment is configured such that each integration circuit calculates in parallel the average values of the signal level values at each predetermined frequency band of the sound signal at a different averaging time, each amplifier at the latter stage of each integration circuit individually weights the calculated average value by using a predetermined weighting factor, the selecting unit selects the representative value based on the weighted average value, the target gain determining unit and the gain comparing unit determine the gain of the sound signal based on the selected representative value, and the amplifier corrects the volume based on the gain.

Also, in the above-described embodiment, although the DSP specialized mainly in the function of correcting the volume has been exemplarily described, the volume correcting apparatus may be configured by the DSP. Also, the “weighting factor” described above in the embodiment may be referred to as “weighting value”.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

Regarding the above-described embodiments, the following embodiments are further disclosed.

(1) Sound equipment having a function of adjusting a volume according to a sound content, including:

a signal level detecting unit configured to sequentially detect a signal level of the sound content; and

a level adjusting unit configured to adjust a level of a sound signal of the sound content to an adjustment value corresponding to a maximum value of the signal level detected by the signal level detecting unit.

(2) In the sound equipment described above in the section (1), the level adjusting unit includes:

a maximum value retaining unit configured to retain the maximum value of the signal level detected by the signal level detecting unit;

a gain determining unit configured to determine a gain from the maximum value retained by the maximum value retaining unit; and

an amplifying unit configured to amplify a sound signal at the gain determined by the gain determining unit.

(3) The sound equipment described above in the sections (1) and (2) further includes a maximum value resetting unit configured to reset the maximum value retained by the maximum value retaining unit at the time of switching the sound content.

What is claimed is:

1. Sound equipment for reproducing a sound signal, comprising:
a plurality of averaging units configured to average an average value of a signal level at each predetermined frequency band of the sound signal at a different averaging time;
a weighting unit configured to weight the average value obtained by the averaging units by using an individual weighting value;
a representative value determining unit configured to obtain a representative value based on the weighted average value; and
a volume correcting unit configured to determine a gain of the sound signal based on the representative value, and correct a volume based on the corresponding gain.

2. The sound equipment according to claim 1,
wherein, within the average value, the average value at which a gain becomes minimum is the representative value.

3. The sound equipment according to claim 1,
wherein the plurality of averaging units comprises at least a first averaging unit using the averaging time corresponding to the sound signal in which a variation of the signal level is rapid, and a second averaging unit using the averaging time longer than the averaging time of the first averaging unit.

4. The sound equipment according to claim 2,
wherein the plurality of averaging units comprises at least a first averaging unit using the averaging time corresponding to the sound signal in which a variation of the signal level is rapid, and a second averaging unit using the averaging time longer than the averaging time of the first averaging unit.

5. The sound equipment according to claim further comprising:
a storing unit configured to store a combination of the weighting values of each weighting unit in association with a predetermined type; and
an acquiring unit configured to acquire the combination corresponding to the type indicated by a designated value based on a user's manipulation, or the type indicated by original data of the sound signal, from the storing unit,
wherein the weighting unit weights the average value by using the weighting value corresponding to the corresponding weighting unit, which is included in the combination acquired by the acquiring unit.

6. The sound equipment according to claim 5,
wherein the type includes a sound source of the sound signal.

7. A volume correcting method for correcting a volume of a sound signal, comprising:
averaging an average value of a signal level at each predetermined frequency band of the sound signal at a different averaging time;
weighting the calculated average value by using an individual weighting value;
determining a representative value based on the weighted average value; and
determining a gain of the sound signal based on the representative value, and correcting a volume based on the corresponding gain.

8. A volume correcting apparatus for correcting a volume of a sound signal based on a volume correction amount set according to a variation in a signal level of the sound signal, comprising:
an initial volume correction amount setting unit configured to set the volume correction amount according to a signal level of an initial part of voice information;
a signal level detecting unit configured to sequentially detect the signal level of the voice information in order of reproduction;
a correction amount deriving unit configured to derive a volume correction amount update value according to the signal level detected by the signal level detecting unit; and
a volume correction amount updating unit configured to update the volume correction amount with the volume correction update value, when a volume is further reduced in a control by the volume correction amount update value than a control by the set volume correction amount.

9. The volume correcting apparatus according to claim 8,
wherein the volume correction amount updating unit compares a signal level detected by the signal level detecting unit with a maximum value of a signal level so far, and determines necessity of updating.

10. The volume correcting apparatus according to claim 8,
wherein the signal level detecting unit further comprises:
a plurality of filters configured to filter the voice information, the plurality of filters having different time constants; and
a filter selecting unit configured to select and determine signal levels outputted from the plurality of filters, depending on a comparison result of output levels of the plurality of filters.
